(19) United States
(12) Patent Application Publication
(10) Pub. No.: US 2024/0085627 A1
(43) Pub. Date: Mar. 14, 2024

(54) Manufacturing Apparatus of Optical Circuit and Manufacturing Method of Optical Circuit

(71) Applicant: Nippon Telegraph and Telephone Corporation, Tokyo (JP)

(72) Inventors: Kenya Suzuki, Musashino-shi, Tokyo (JP); Keita Yamaguchi, Musashino-shi, Tokyo (JP); Ai Yanagihara, Musashino-shi, Tokyo (JP); Masashi Ota, Musashino-shi, Tokyo (JP)

(21) Appl. No.: 18/262,413

(22) PCT Filed: Feb. 26, 2021
(86) PCT No.: PCT/JP2021/007507

§ 371 Date: Jul. 21, 2023

(51) Int. Cl. G02B 6/132; C03B 19/14; G03F 7/00

(52) U.S. Cl. CPC G02B 6/132; C03B 19/1407; G03F 7/001; G03F 7/0035

(57) ABSTRACT

An optical circuit to be manufactured on a wafer has a problem that characteristics are distributed (biased) in a wafer plane due to various causes in manufacturing. The present invention is characterized in that refractive index distribution of an upper cladding is adjusted on the basis of refractive index distribution of a lower cladding and a core film, a film thickness of the core film, and in-plane distribution such as an execution refractive index of an optical waveguide (calculated from a width of a core pattern).

### TECHNICAL FIELD

The present invention relates to a silica-based planar lightwave circuit that is an optical waveguide component manufactured by a flame deposition method.

### BACKGROUND ART

An optical device such as a semiconductor laser, a photodiode, an optical wavelength multiplexer/demultiplexer, and an optical switch includes an optical integrated circuit. In optical fiber communication, not only an optical fiber as a transmission medium but also an optical integrated circuit in these optical devices for performing optical signal processing plays an important role (see, for example, Non Patent Literature 1). The semiconductor laser generates an optical wave for superimposing a signal as an oscillator of light, and the photodiode operates as an element that converts intensity of an optical signal into an electric signal. In addition, the optical wavelength multiplexer/demultiplexer typified by an arrayed waveguide grating is used for wavelength division multiplexing communication as an element that multiplexes/demultiplexes different wavelengths of light (see, for example, Non Patent Literature 2). The optical switch has an important function in a reconfigurable optical add/drop multiplexing (ROADM) system as an element that routes a path of light. These optical integrated circuits are generally constituted by optical waveguides formed on a substrate. The optical waveguide includes a core through which an optical signal propagates and a cladding surrounding the core. The semiconductor laser and the photodiode are made of a semiconductor material such as InP, and the arrayed waveguide grating and the optical switch are mainly made of an optical waveguide material including quartz glass.

FIG. 1 is a block diagram illustrating a method for manufacturing an optical waveguide. A silica-based planar lightwave circuit formed with silica-based glass will be described as an example. First, in step 1 of lower cladding deposition, a glass film to be a lower cladding 12 is deposited on a silicon substrate (wafer) 11. The lower cladding 12 is made of, for example, SiO₂ to which P₂O₅ or B₂O₃ is added deposited by a flame hydrolysis deposition (FHD) method. Soot-like glass particles deposited by the FHD method are heated at a high temperature of 1000° C. or higher to obtain a transparent lower cladding 12. Next, in step 2 of core deposition, thin film glass to be the core 13 having a refractive index higher than that of the lower cladding 12 is deposited using the flame hydrolysis deposition (FHD) method in a similar manner. In the deposition of the core 13, for example, a desired refractive index value can be obtained by adding GeO₂ to SiO₂. Similarly to step 1 of lower cladding deposition, heating is performed at a high temperature of 1000° C. or higher to form a transparent core 13. It goes without saying that the lower cladding and the core may be formed not only by the FHD method but also by other known methods.

In step 3 of photoresist film formation, a photoresist film 14 is formed on the substrate by spin coating. Next, in step 4 of circuit pattern exposure, a circuit pattern corresponding to a mask pattern is exposed by irradiating the photoresist film with UV light 16 via a photomask 15. Then, in step 5 of photoresist development, the circuit pattern of the photoresist film is developed to obtain a photoresist pattern 17.

Next, in step 6 of etching, the photoresist pattern 17 is transferred to the core by reactive ion etching (RIE) to obtain a core pattern 18. Then, in step 7 of resist removal, the photoresist remaining on the core is removed by asking. Finally, in step 8 of upper cladding deposition, an upper cladding 19 is deposited by the same method as the lower cladding deposition in step 1 of lower cladding deposition.

### CITATION LIST

### Non Patent Literature

Non Patent Literature 1: Fundamentals of Optical Waveguides Second edition (2010/8/4), P. 437

Non Patent Literature 2: A. Himeno, K. Kato and T. Miya, “Silica-based planar lightwave circuits,” in IEEE Journal of Selected Topics in Quantum Electronics, vol. 4, no. 6, pp. 913-924, November-December 1998, doi:10.1109/2944.736076.

### SUMMARY OF INVENTION

Various characteristics such as optical characteristics are inspected for an optical waveguide obtained in the above manufacturing step. In related art, in order to reflect the inspection result in the manufacturing step, manufacturing conditions reflecting the inspection result are set in each step after a series of steps are all completed. In this method, manufacturing errors in the respective steps are accumulated, which causes a problem that accuracy of the inspection result becomes lower in the later steps. On the other hand, it is possible to prevent manufacturing errors from being accumulated by resetting the manufacturing conditions of the step or adjusting the manufacturing conditions of the subsequent step from the inspection result obtained at the end of one step.

Thus, if information on a processing result obtained in a certain step, for example, information on a resist pattern width obtained in the photolithography step can be known immediately after the step of the photolithography step, a step reflecting the information on the pattern width can be performed in the etching step which is a subsequent step. In addition, if a film thickness and a refractive index of the core obtained in the core deposition step can be known immediately after the deposition step, optical characteristics of the optical waveguide formed in the subsequent photolithography step or etching step can be predicted. As described above, it is also advantageous in terms of throughput of the manufacturing step if the information on the optical waveguide component obtained in the previous step can be acquired during or immediately after the previous step and reflected in processing conditions of the subsequent step or used to predict the optical characteristics obtained in the subsequent step.

In particular, in the FHD method that can be used in step 1 of lower cladding deposition, step 2 of core deposition, and step 8 of upper cladding deposition in the above-described manufacturing step, soot (soot) of glass is baked by spraying a source gas hydrolyzed by a burner to a wafer installed on a rotating turntable. In this event, the film thickness and the refractive index fluctuate in a wafer plane due to various causes such as an environmental temperature, fluctuation of rotation speed of the turntable and discretization and fluctuation of an orbit of the burner. In addition, manufacturing fluctuation also occurs in the photolithography step from step 3 of photoresist film formation to step 5 of photoresist development. In the spin coating of the photoresist in step 3 of photoresist film formation, a thick layer of resist may be formed on an outer periphery of the wafer due to the influence of surface tension at an edge of the wafer. Also in the exposure step in step 4 of circuit pattern exposure, distribution of an exposure amount occurs in a wafer plane due to unevenness in illuminance of UV light of exposure machine, or the like. Furthermore, also in the development step in step 5 of photoresist development, in-plane distribution (bias) of a development amount may occur due to a difference in timing at which a developer is dropped onto the wafer and wet-spreads. A manufacturing bias due to preceding steps 3 to 5 may affect the film thickness, the refractive index, and the like, of the upper cladding finally formed in step 8 of upper cladding deposition that is the subsequent step.

Although the silica-based planar lightwave circuit has been described above as an example, optical semiconductor waveguides such as lasers and photodetectors, ferroelectric waveguides such as LiNbO₃, silicon waveguides using silicon as a waveguide material, and the like, have similar problems.

The present invention provides a stone optical circuit in which refractive index distribution of an upper cladding finally formed in an upper cladding deposition step is adjusted on the basis of measurement data measured in a step before the upper cladding deposition step.

An aspect according to an embodiment of the present invention is a method for manufacturing an optical circuit including a glass film manufactured by a glass film forming method by a flame deposition method, the method including: a step of forming a lower cladding film; a step of forming a core film; a step of forming a core pattern by photolithography; and a step of forming an upper cladding film on the core pattern, in which in the step of forming the upper cladding film, refractive index distribution of the upper cladding is adjusted on the basis of measurement data of refractive index distribution in a layer of the optical circuit before the step of forming the upper cladding film.

The measurement data is refractive index distribution of the lower cladding in a wafer plane, refractive index distribution and/or a film thickness of the core film, in-plane distribution of an effective refractive index of the optical waveguide calculated from a width of the core pattern.

The refractive index distribution of the upper cladding may be adjusted such that a silica-based planar lightwave circuit (an optical circuit to be formed by a silica-based planar lightwave) satisfies desired circuit characteristics.

The refractive index distribution of the upper cladding may be adjusted such that an effective refractive index of the optical waveguide becomes constant in a plane.

The refractive index of the upper cladding may be adjusted by one or both of P₂O₅ and B₂O₃.

The refractive index of the upper cladding may be adjusted by adding GeO₂, TiO₂, Ta₂O₅, HfO₂, ZrO₂, or the like.

In addition, the present invention may be a method for manufacturing an optical circuit including a glass film manufactured by a glass film formation method by a flame deposition method, the method including a step of forming a lower cladding film, a step of forming a core film, a step of forming a core pattern by photolithography, and a step of adjusting refractive index distribution of an upper cladding on the basis of refractive index distribution of the lower cladding in a wafer plane, refractive index distribution of the core film, a film thickness, and in-plane distribution of an effective refractive index of an optical waveguide calculated from a width of the core pattern.

### BRIEF DESCRIPTION OF DRAWINGS

FIG. 1 is a view illustrating a manufacturing step of an optical waveguide.

FIG. 2 is a view for explaining a method for manufacturing an optical device according to an embodiment of the present invention.

FIG. 3 is a block diagram illustrating a feedforward system according to the embodiment of the present invention in a generalized manner.

FIG. 4 is a schematic view of data processing according to the embodiment of the present invention.

FIG. 5 is a view illustrating a dry etching apparatus according to the embodiment of the present invention.

FIG. 6 is a schematic view of a flame hydrolisys deposition (FHD) apparatus for depositing glass.

FIG. 7 is a view illustrating that glass particles are deposited on a wafer.

FIG. 8(a) is a view illustrating effective refractive index dependency on change in a waveguide core width, and FIG. 8(b) is a view illustrating an absolute value of a refractive index of a cladding layer and effective refractive index dependency on the cladding refractive index.

FIG. 9(a) is a view illustrating grid-like points selected as representative points in the wafer. FIG. 9(b) is a view illustrating points placed on polar coordinates (r, θ) selected as representative points in the wafer.

FIG. 10(a) is a view illustrating a pattern of an optical circuit that compensates for distribution of a refractive index and a film thickness. FIG. 10(b) is a view illustrating circuit patterns of arrayed waveguide gratings having different optical path differences dL.

FIG. 11(a) is a view illustrating an example of depositing glass fine particles on a wafer. FIG. 11(b) is a view illustrating an example of adjustment of a gas flow rate of a burner.

FIG. 12 is a view illustrating an arrayed waveguide grating according to Example 3.

FIG. 13(a) is a view illustrating arrangement of reticles. FIG. 13(b) is a view illustrating a thickness of an arrayed waveguide of each reticle pattern.

### DESCRIPTION OF EMBODIMENTS

Hereinafter, an embodiment of the present invention will be described in detail with reference to the drawings.

### Basic Configuration

A manufacturing method according to an embodiment of the present invention includes: measuring components or characteristics of an optical device formed in one step in a manufacturing step at that time and adjusting or correcting manufacturing conditions in a subsequent step on the basis of the measurement data (hereinafter, this scheme will be referred to as a “feedforward system”). The feedforward system makes it possible to obtain desired optical characteristics for the finally obtained optical device, in which variations in the optical characteristics of the optical device are reduced.

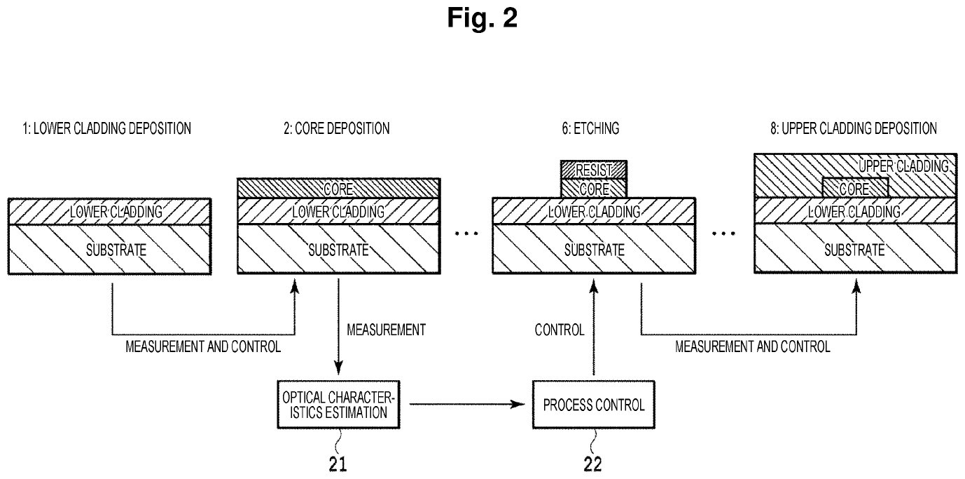

FIG. 2 is a view illustrating an example of a method for manufacturing an optical waveguide according to an embodiment of the present invention. In the feedforward system, “measurement” is performed on components of the optical device formed in one step, and “optical characteristics estimation” is performed by optical characteristics estimation processing 21 on the basis of the measurement result. Then, “control” of the subsequent step is performed by process control processing 22 on the basis of the estimation result.

For example, a refractive index and a thickness of a lower cladding film formed in step 1 of lower cladding deposition, and a refractive index and a thickness of a core layer deposited in step 2 of core deposition are “measured”. On the basis of the measurement results, final optical characteristics of the device manufactured with standard (nominal) design values are estimated. Then, on the basis of this estimation, intensity or a period of etching is “controlled” in step 6 of etching which is a subsequent step.

Specifically, an ideal core width of a pattern for satisfying performance required as an optical device is estimated (predicted) on the basis of the “measured” film thickness and refractive index of the core layer and the refractive index of the cladding film. Then, in step 6 of etching, etching is performed on the basis of the prediction value. For example, in a case of prediction information that “a waveguide width after core processing is increased, and desired performance cannot be satisfied” with the standard (nominal) design values, correction is performed to narrow the core width to be formed in the etching step. As an adjustment method in this event, a method in which the core width is made narrower than a standard (nominal) value by increasing a period of etching or increasing intensity of etching can be considered. Furthermore, it is also possible to “measure” the width and a level difference of the core in the pattern of the waveguide formed in step 6 of etching, “control” the refractive index, and the like, of the upper cladding film formed in step 8 of upper cladding deposition on the basis of the measurement result and adjust the optical characteristics of the finally obtained optical waveguide.

As described above, in the feedforward system of the present embodiment, shapes, characteristics, and the like, of the components of the formed optical device are measured during or after the preceding step among a plurality of steps of manufacturing the optical device, and the manufacturing conditions are adjusted or corrected in the subsequent step on the basis of the measurement result such that performance of the finally completed device satisfies desired conditions.

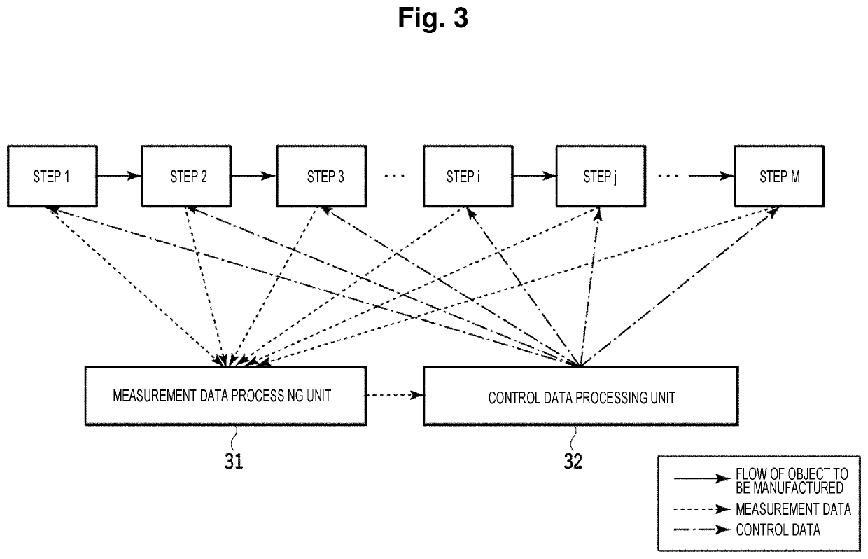

FIG. 3 is a view illustrating the feedforward system according to the embodiment of the present invention in a generalized manner. The feedforward system includes manufacturing procedure of an optical device including M steps, and the optical device to be manufactured is manufactured in the order of step 1, step 2 . . . , step i, . . . step j, . . . step M. Here, when i<j, step j is a step temporally after step i. The feedforward system includes a measurement data processing unit 31 and a control data processing unit 32. The measurement data processing unit 31 executes the optical characteristics estimation processing 21 described above with reference to FIG. 2, and the control data processing unit 32 executes the process control processing 22. The measurement data processing unit 31 and the control data processing unit 32 can be in a form of a computer including a CPU, a RAM, a ROM, and the like.

In FIG. 3, a solid line indicates flow according to the steps of an object to be manufactured. In addition, a dashed line indicates measurement data obtained by “measurement” in each step, and an alternate long and short dash line indicates control data for “control” for each step. As described above, in the feedforward system of the present embodiment, in step i, measurement data is acquired from a manufacturing apparatus related to manufacturing or a measurement apparatus and is transferred to the measurement data processing unit 31. The measurement data processing unit 31 predicts shapes or characteristics of components of the optical device formed in step i on the basis of the measurement data. Alternatively, optical characteristics of the optical device finally obtained in step i may be predicted on the basis of the measurement data.

The prediction value derived by the measurement data processing unit 31 is passed to the control data processing unit 32. The control data processing unit 32 obtains manufacturing conditions in step j, which is a subsequent step, on the basis of the prediction value. When step j is executed, the control data processing unit 32 supplies control data for step j set in the manufacturing apparatus according to the obtained manufacturing conditions. The control data based on the preceding step supplied when the subsequent step j is executed may be only the control data based on the preceding step i or may be a plurality of types of control data based on some of the preceding steps. It is a matter of course that a form of the control data is determined according to conditions of an actually configured manufacturing apparatus and an object to be manufactured.

### Example 1

n the following, specific examples of waveguide manufacturing by the above-described feedforward system will be described. The following example relates to a configuration for obtaining control data for step 8 of upper cladding deposition (step k) on the basis of measurement data obtained in step 6 of etching (step i).

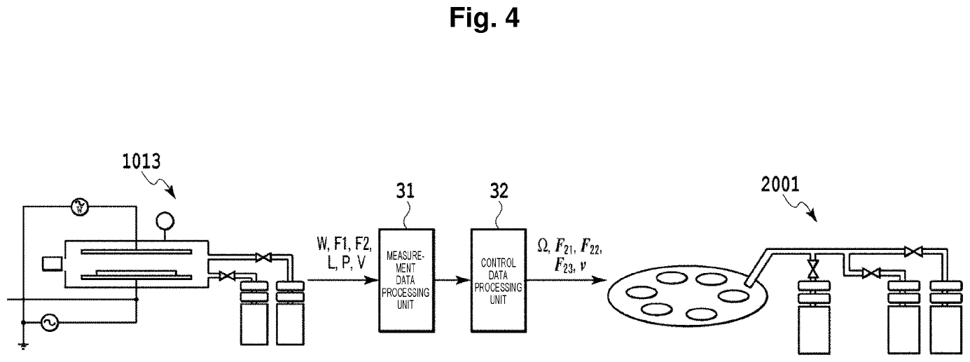

FIG. 4 is a view illustrating a manufacturing system according to the present embodiment and extracts and illustrates only step 6 of etching as step i, step 8 of upper cladding deposition as step k, the measurement data processing unit, and the control data processing unit in a basic configuration system illustrated in FIG. 3. Step 6 of etching is performed by a dry etching apparatus 1013, and time-series values W(t), F1(t), F2(t), L(t), P(t), and V(t) of reading of the measurement apparatuses measured in the etching step are transmitted to the measurement data processing unit 31. The measurement data processing unit 31 performs prediction by calculating a nominal model of optical characteristics λₙₒₘ (x, y) as an optical device according to Formula 1 on the basis of each time-series value. In addition, the control data processing unit 32 generates control values of the FHD method in step 8 of upper cladding deposition on the basis of the prediction value of the optical characteristics by the measurement data processing unit 31. Then, an FHD apparatus 2001 performs the FHD method on the basis of the generated control values to deposit the upper cladding.

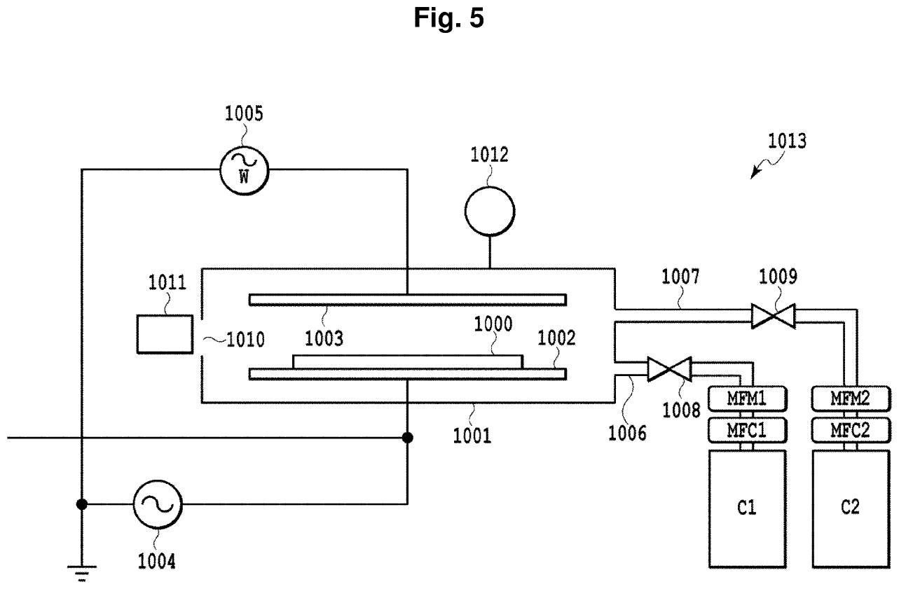

FIG. 5 is a schematic view illustrating the dry etching apparatus 1013 illustrated in FIG. 4. The dry etching apparatus 1013 performs patterning of the core of the optical waveguide. In FIG. 5, a wafer 1000 to be processed is placed on an RF electrode 1002 placed inside a vacuum chamber 1001 of the dry etching apparatus 1013. Another counterpart RF electrode 1003 is disposed above the RF electrode 1002, and an RF signal is supplied from an RF power supply 1004. In the RF electrode 1002, an RF power meter 1005 is installed, and RF power is observed. Further, connection pipelines 1006 and 1007 are connected to the vacuum chamber 1001 and are respectively connected to cylinders C1 and C2 via valves 1008 and 1009, mass flow meters MFM1 and MFM2, and mass flow controllers MFC1 and MFC2. An etching gas is supplied from the cylinders C1 and C2 to the vacuum chamber 1001. As the etching gas, a CF-based or SF-based active gas or an inactive gas such as Ar is used, and both may be mixed. Here, an example of two systems of cylinders C1 and C2 is illustrated, but the number thereof is arbitrary. Further, an observation window 1010 is installed in the vacuum chamber 1001, and an internal plasma state is observed by an emission detector 1011 through the observation window 1010. In addition, a vacuum gauge 1012 is installed in the vacuum chamber 1001 to measure a degree of vacuum inside the vacuum chamber 1001. The reading of each measurement apparatus is defined as follows.
Reading of RF power: W
Reading of mass flow meter: F1 and F2
Reading of emission detector: (wavelength) L, (intensity) P
Reading of vacuum gauge: V

The core of the optical waveguide is processed by the dry etching apparatus 1013 illustrated in FIG. 5, but a processing amount and distribution in a wafer plane depend on the RF power, a flow rate of the supply gas, a state of plasma, and the degree of vacuum. As a cause of bias in the wafer plane, for example, a fresh gas is supplied in a region close to the connection pipeline 1006 and the connection pipeline 1007 of the supply gas, whereas a deteriorated gas contributes to etching in the vicinity of a vent port (not illustrated in FIG. 5). In addition, the bias in the wafer plane occurs as a result of an edge effect of an electric field becoming remarkable at end portions of the RF electrode 1002 and the RF electrode 1003, which makes a degree of plasma generation different.

The measurement result in the dry etching step can be fed forward to the FHD step, for example.

The measurement data obtained above is subjected to the following processing by the measurement data processing unit 31. Specifically, the measurement data processing unit 31 performs prediction by calculating a nominal model of the optical characteristics λₙₒₘ(x, y) as an optical device according to the following Formula 1 on the basis of the time-series value of each measurement data.

Math. 1

λₙₒₘ(x, y)=f_{xy}(W, F₁, F₂, L, P, V) (Formula 1)

In Formula 1, x and y are coordinates in a wafer plane. λₙₒₘ is optical characteristics. For example, in a case of an arrayed waveguide grating, λₙₒₘ is a transmission center wavelength, a crosstalk, a polarization dependent loss, a wavelength dependent loss, a polarization dependent transmission wavelength, wavelength dispersion, polarization mode dispersion, or the like.

The nominal model f_{xy}(W, F₁, F₂, L, P, V) can be expressed as, for example, a power sum of each parameter. In other words, in a case where an average value of the optical characteristics over a plurality of times K-1 of manufacturing before certain K-th manufacturing is set as λ^{Avg}(x, y), and averages of the measured values are set as W_{avg}, F_{1avg}, F_{2avg}, L_{avg}, P_{avg}, and V_{avg}, the nominal model can be expressed as:

$$\begin{matrix}Math . 2 & \\ {f}_{xy} ( W , {F}_{1} , {F}_{2} , L , P , V ) - {λ}^{Avg} ( x , y ) = {\sum }_{j = 0}^{{n}_{W}} {{C}_{W} ( W - {W}_{avg} )}^{j} + {\sum }_{j = 0}^{{n}_{{F}_{1}}} {{C}_{{F}_{1}} ( {F}_{1} - {F}_{1 avg} )}^{j} + {\sum }_{j = 0}^{{n}_{{F}_{2}}} {{C}_{{F}_{2}} ( {F}_{2} - {F}_{2 avg} )}^{j} + {\sum }_{j = 0}^{{n}_{L}} {{C}_{L} ( L - {L}_{avg} )}^{j} + {\sum }_{j = 0}^{{n}_{P}} {{C}_{p} ( P - {P}_{avg} )}^{j} + {\sum }_{{j = 0}^{}}^{{n}_{V}} {{C}_{V} ( V - {V}_{avg} )}^{j} . & ( Formula 2 )\end{matrix}$$

Here, coefficients C_{w}, C_{F1}, C_{F2}, C_{L}, C_{P}, and C_{V} are determined for each coordinate (x, y) in the wafer. In addition, it can be assumed that each measurement value in the K-th manufacturing has small deviation from the average of previous measurement values, and thus, each sum may be obtained by adding the first terms. In addition, while it is assumed here that change from the average value of each measurement value is minute and each measurement value is independent, a formula f_{xy}(W, F₁, F₂, L, P, V) of a nominal model assuming a case where each measurement value is dependent may be defined. For example, if the gas flow rates F₁ and F₂ change, the degree of vacuum V also changes, and thus, the nominal model may include the product of both and light relating to V(F₁, F₂). In addition to the power sum, the coefficients may be obtained by machine learning, or the like.

Noe that the coefficients may be obtained by AI/machine learning on the basis of the inspection result performed in the middle of the manufacturing step of the optical waveguide, and the final device characteristics may be predicted. As training data of AI, data in which step inspection results and device characteristics of optical waveguides manufactured so far are combined can be utilized.

In addition, in the embodiment described above, the reading W of the RF power, the readings F₁ and F₂ of the mass flowmeter, the reading (wavelength) L of the emission detector, the (intensity) P, and the reading V of the vacuum gauge are used as measurement items, but other measurement values, for example, an emission spectrum obtained from the emission detector, a temperature, humidity, an atmospheric pressure, weather, a timing of overhaul of the apparatus, the number of times of processing from the overhaul, and the like, may be added.

An example using FHD will be described below.

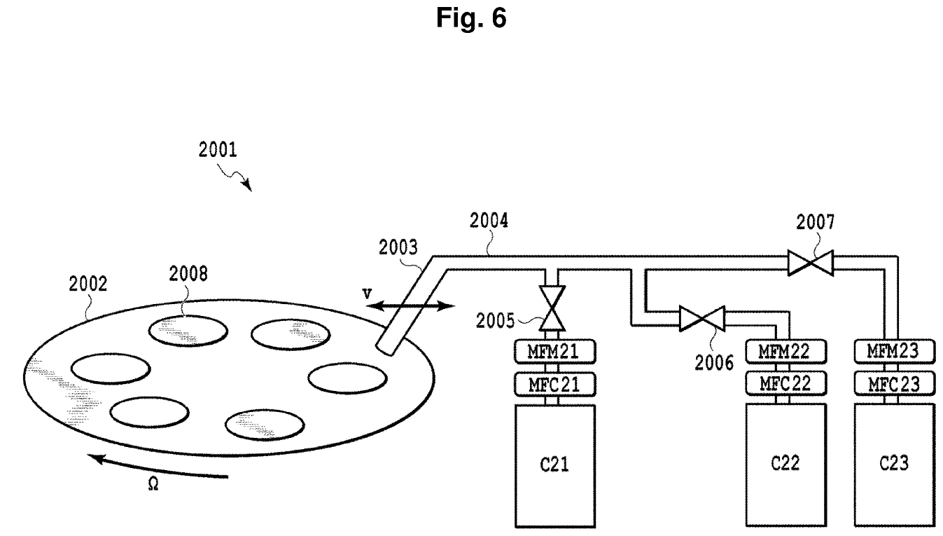

FIG. 6 is a schematic view illustrating a flame hydrolisys deposition (FHD) apparatus 2001 illustrated in FIG. 4. In FIG. 6, the wafer 2008 is placed on the turntable 2002 that rotates at angular velocity Q. The burner 2003 is disposed above the turntable 2002 and is connected to the valves 2005, 2006, and 2007 via a pipeline 2004. The valves 2005, 2006, and 2007 are respectively connected to the cylinders C21, C22, and C23 via the mass flow meters MFM21, MFM22, and MFM23, the mass flow controllers MCF21, MCF22, and MCF23. A source gas such as SiCl₄, BCl₃, and POCl₃ is sealed in the cylinders C21, C22, and C23, and flow rates thereof are adjusted and mixed by the mass flow controllers MCF21, MCF22, and MCF23, and supplied to the burner 2003. BCl₃ has an effect of reducing a refractive index of glass, and POCl₃ has an effect of increasing the refractive index of glass.

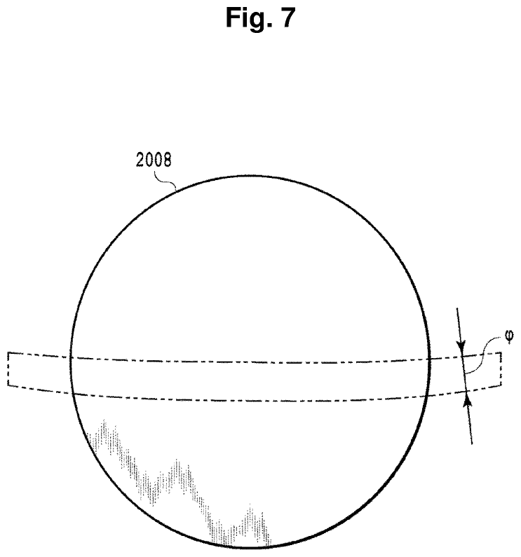

Oxygen and hydrogen (not illustrated) are simultaneously supplied to the burner. The source gas is hydrolyzed in an oxyhydrogen flame to produce glass microparticles, which are deposited on the wafer. The burner 2003 moves in a radial direction above the turntable 2002 rotating at the angular velocity Q. Thus, as illustrated in FIG. 7, the glass particles are deposited on the wafer 2008 with respect to a region φ of about an inner diameter of a tube of the burner 2003 per rotation of the turntable 2002.

Here, as control values,
rotation angular velocity of turntable: Ω
readings of mass flow meter: F21, F22, F23, and
movement speed of the burner in the radial direction: v are defined. These control values are observable. In the following description, it is assumed that the upper cladding layer is formed by the FHD method after the core processing.

The nominal model of the optical characteristics λ′ₙₒₘ(x, y) as the optical device in step 8 of upper cladding deposition is described as:

Math. 3

λ′ₙₒₘ(x, y)=f′_{xy}(Ω, F₂₁, F₂₂, F₂₃, v) Formula (3).

Here, x and y in Formula (3) are coordinates in the wafer plane. λ′ₙₒₘ is optical characteristics. For example, in a case of an arrayed waveguide grating, λ′ₙₒₘ is a transmission center wavelength, a crosstalk, a polarization dependent loss, a wavelength dependent loss, a polarization dependent transmission wavelength, wavelength dispersion, polarization mode dispersion, or the like. In a case of an optical switch, examples of the optical characteristics can include a loss, an extinction wavelength, a crosstalk, a polarization dependent loss, and the like.

The nominal model f′_{xy}(Ω, F₂₁, F₂₂, F₂₃, and v) can be expressed as, for example, a power sum of each parameter. In other words, in a case where an average value of optical characteristics over a plurality of times K-1 of manufacturing before certain K-th manufacturing is set as λ^{Avg}(x, y), and averages of measurement values of control values are set as Ω_{avg}, F_{21avg}, F_{22avg}, F_{23avg}, and v_{avg}, the nominal model can be expressed as:

$$\begin{matrix}Math . 4 & \\ {f}_{xy}^{′} ( Ω , {F}_{21} , {F}_{22} , {F}_{23} , v ) - {λ}^{Avg} ( x , y ) = {\sum }_{j = 0}^{{n}_{Ω}} {{C}_{Ω} ( Ω - {Ω}_{avg} )}^{j} + {\sum }_{j = 0}^{{n}_{{F}_{21}}} {{C}_{{F}_{21}} ( {F}_{21} - {F}_{21 avg} )}^{j} + {\sum }_{j = 0}^{{n}_{{F}_{22}}} {{C}_{{F}_{22}} ( {F}_{22} - {F}_{22 avg} )}^{j} + {\sum }_{j = 0}^{{n}_{{F}_{23}}} {{C}_{F 23} ( {F}_{23} - {F}_{23 avg} )}^{j} + {\sum }_{j = 0}^{{n}_{v}} {{C}_{v} ( v - {v}_{avg} )}^{j} . & Formula ( 4 )\end{matrix}$$

As described above, the formula of the nominal model may be in a form other than the power sum. In the formula of the nominal model, Ω, F₂₁, F₂₂, F₂₃, and v are measurement values and control values.

he measurement data including the measurement values and the control data including the control values may be accumulated in a database.

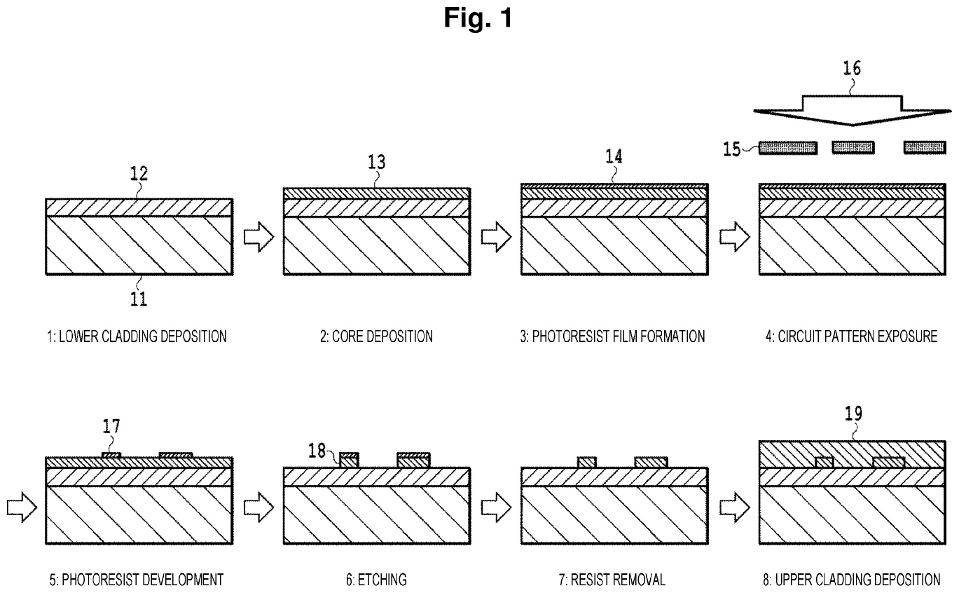

The control data processing unit 32 generates control data as follows. For example, taking a silica-based planar lightwave circuit as an example, as illustrated in FIG. 1, the upper cladding 19 is deposited and embedded after core processing. Thus, the optical characteristics λₙₒₘ(x, y) of the optical device obtained from the nominal model at the time of core processing in step 6 of etching described above and the nominal model λ′ₙₒₘ(x, y) of the optical characteristics in the upper cladding deposition are used to generate control values Ω, F₂₁, F₂₂, F₂₃, and v of the FHD method at the time of deposition of the upper cladding 19 so that

Math. 5

[λₙₒₘ(x, y)−λ_{target}(x, y)]+[λ′ₙₒₘ(x, y)−λ_{target}(x, y)]=0 Formula (5)
is satisfied at each position (x, y) in the wafer plane. As a result, it is possible to obtain desired optical characteristics λ_{target}(x, y) of an optical device with no distribution of optical characteristics.

In feedforward correction, a controllable parameter (upper Ω, F21, 22, . . . , etc.) may be controlled so as to satisfy Formula (5). The above formula of the nominal model is expressed to represent controllability. In other words, the left side of Formula (5) is an evaluation function, and if Formulas (1) and (3) are substituted into Formula (5), the evaluation function is expressed by the sum of powers of the controllable parameters for each step. It is only necessary to perform manufacturing while adjusting each control parameter so that the evaluation function becomes zero. The control may be performed by selecting one of the control parameters that most efficiently satisfies the evaluation function.

A method described below is means for obtaining data to be output. In deriving the control parameters to be output, first, the measurement values of the known control parameters obtained in step 6 of etching are substituted into the formula obtained by substituting Formula (1) and (3) into Formula (5). The control parameters Ω_{avg}, F_{21avg}, F_{22avg}, F_{23avg}, and v_{avg} in step 8 of upper cladding deposition are variables of the same formula, but each parameter can be determined using a method such as a hill-climbing method, a method using a genetic algorithm, and Particle Swarm Optimization. In a case where Formula (3) is linear, each parameter can also be determined by using a simple method such as linear programming.

Specific description will be given. For example, the center wavelength of the arrayed waveguide grating is expressed as:

Math. 6

λ₀=n_{eff}dL/m Formula (6).

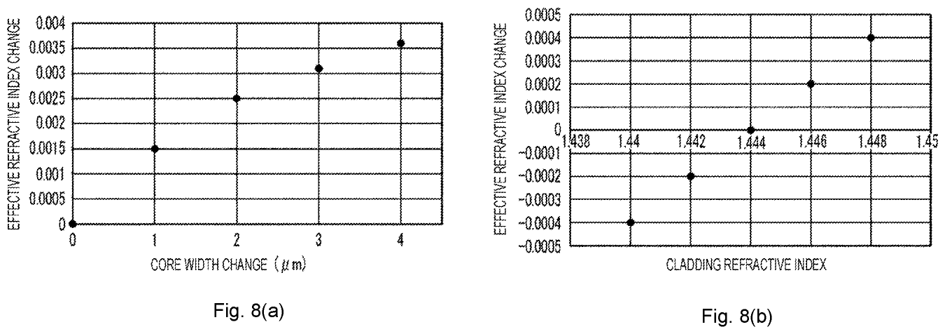

Here, n_{eff} is an effective refractive index of the arrayed waveguide, dL is an optical path length difference between the waveguides of the arrayed waveguide, and m is diffraction order. In other words, the center wavelength of the arrayed waveguide grating depends on the effective refractive index n_{eff}. The effective refractive index neff increases as the width and height of the waveguide core increase and increases as the refractive index of the cladding increases. FIG. 8(a) is a view illustrating the effective refractive index dependency on the waveguide core width. FIG. 8(b) is a view illustrating change in the absolute value of the refractive index of the cladding layer and the effective refractive index dependency on the cladding refractive index. For example, in the core processing step, in a case where it is predicted by calculation from the nominal model at the time of reactive ion etching that the core width increases and the desired effective refractive index increases, it is only necessary to lower the refractive index of the upper cladding by adjusting the source gas at the time of upper cladding deposition by the FHD method. In the right side of Formula (3) of the nominal model of the FHD method

Math. 7

f′_{xy}(Ω, F₂₁, F₂₂, F₂₃, v) right side of Formula (3),
the above is achieved by increasing the flow rate of BCl₃ that lowers the refractive index of the glass.

Although the method in which the deviation of distribution in the wafer plane from a target value in the core processing is compensated for at the time of the upper cladding deposition has been described as an example, it is obvious that the deviation can be compensated for between other steps. For example, it is also possible to correct the distribution during the deposition of the core film in subsequent steps, for example, a photolithography step, a core processing step, and an upper cladding film formation step (step 8 of upper cladding film formation), and it is also possible to correct the distribution during the photolithography in the core processing step and the upper cladding film formation step. Furthermore, it is obvious that the distribution at the time of core deposition can be corrected by combining the photolithography step and the core processing.

Here, the center wavelength of the arrayed waveguide grating has been described as an example, but similarly, a crosstalk and polarization dependence may be corrected as optical characteristics, or an extinction wavelength and a loss of an optical switch by a Mach-Zehnder interferometer may be corrected. Furthermore, a plurality of indexes among them may be corrected.

Further, in correction of an oscillation wavelength of a distributed Bragg reflector (DBR) type semiconductor laser, an oscillation wavelength Ao of the Gragg grating is expressed as:

Math. 8

λ₀=2n_{eff}Λ (Formula 7).

Thus, n_{eff} can be corrected between steps in a similar manner. In the manufacturing step of the semiconductor laser, a refractive index of an epitaxially grown InP waveguide varies depending on composition. Deviation of the refractive index from the absolute value or the distribution in the wafer plane generated in the growth step may be corrected using the parameters W, F₁, F₂, L, P, and V at the time of etching as control values.

Although the FHD has been described above as an example, other methods such as chemical phase vapor deposition (CVD) and physical phase vapor deposition (PVD) may be used. In a method such as CVD and PVD, a glass film is collectively formed on the entire surface of the wafer without scanning a wafer position with a burner. In this case, as described above, the optical characteristics may be corrected on the basis of (Formula 1) for each apparatus calculated on the basis of the time-series values W(t), F1(t), F2(t), L(t), P(t), and V(t) of reading of each measurement apparatus of the manufacturing apparatus.

The present embodiment discloses an optical device manufacturing system including M (M is an integer of 2 or more) steps, the optical device manufacturing system including at least one measurement data processing unit configured to input and process measurement data from a manufacturing apparatus or a measurement apparatus in an i-th step and at least one control data processing unit configured to process the measurement data and output the processed measurement data to a manufacturing apparatus in a j-th step, where M is an integer of 2 or more, i is a natural number, j is an integer of 2 or more, and i<j. With this optical device manufacturing system, in manufacturing an optical waveguide component including a plurality of steps, in a certain step (j-th step), conditions of the step (j-th step) can be adjusted using the measurement data from the manufacturing apparatus or the measurement apparatus in a step (i-th step) before the step.

### Example 2

In the present embodiment, correction of the upper cladding (overcladding) will be described.

In photolithography, there is a case where a target pattern width does not be a desired width due to causes such as in-plane distribution of a resist film thickness, distribution of a degree of development caused by deterioration of a developer due to a pattern density, and distribution of illuminance in a plane of an exposure apparatus. The deviation of the circuit pattern width from the target value due to these causes can be corrected in a subsequent step. In other words, by correcting the distribution of the effective refractive index in the film formation step (upper cladding deposition) 8 of the upper cladding 19 in the manufacturing step of the standard silica-based planar lightwave circuit in FIG. 1, it is also possible to correct the distribution of the effective refractive index caused by the waveguide width.

In the present embodiment, the in-plane distribution of width dimension of the core pattern 18 is measured after the photoresist pattern 17 is removed in step 7 in FIG. 1. After the width distribution is measured, distribution of the effective refractive index described in Example 1 is obtained, and the upper cladding 19 to be formed in step 8 is caused to have a refractive index distribution so as to correct the distribution.

FIG. 6 is a view illustrating deposition of glass particles on the wafer. In the FHD method illustrated in FIG. 6, the wafer is disposed on a turntable rotating in a Ω direction, and a burner that discharges the glass fine particles moves in a v direction. In other words, on one round of the turntable, the glass particles are deposited as in the trajectory illustrated in FIG. 6. Glass is deposited by temporally adjusting the flow rate of the source gas so as to compensate for the distribution of the effective refractive index previously obtained with respect to this trajectory.

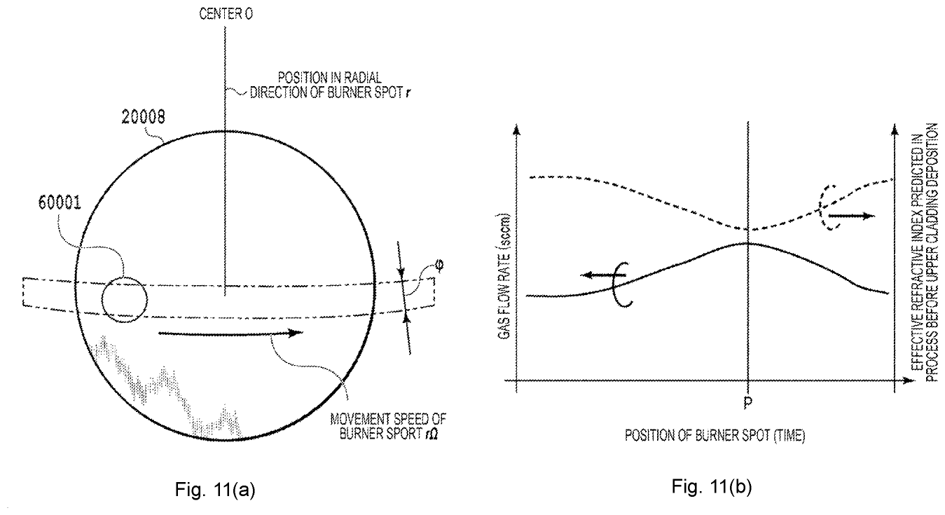

As illustrated in FIG. 11(a), the burner deposits glass fine particles in a region of a spot 60001 at a certain moment according to the diameter of the burner, and assuming that a position of the burner is r in the radial direction of the spot, the spot 60001 moves as illustrated at moving speed rΩ according to rotation of the turntable. Here, with reference to FIG. 8, the gas flow rates of MFM 21 to MFM 23 are adjusted.

FIG. 11(b) is an example illustrating adjustment of the gas flow rates. The horizontal axis indicates the position of the burner spot, and this position is set by time. The vertical axis indicates the gas flow rate (sccm). A dotted line in FIG. 11(b) is the effective refractive index of the waveguide predicted in the step up to the upper cladding deposition predicted from FIG. 8. As indicated by the dotted line in FIG. 11(b), the effective refractive index takes a minimum value at the position P of the burner. The gas flow rate at the time of forming the upper cladding film is adjusted, and the flow rate of the source gas is adjusted so that the effective refractive index increases at the position P, for example, so as to increase concentration of P₂O₅ or decrease concentration of B₂O₃. At a position where the effective refractive index is high, adjustment may be performed to decrease the concentration of P₂O₅ or increase the concentration of B₂O₃. In addition, the distribution of the effective refractive index may be corrected by adding GeO₂, TiO₂, Ta₂O₅, HfO₂, or ZrO₂ and adjusting the concentration thereof. In addition, the refractive index of the upper cladding may be lowered by adding fluorine.

In the present embodiment, the refractive index distribution of the upper cladding is adjusted on the basis of the refractive index distribution of the lower cladding and the core film, the film thickness of the core film, and the in-plane distribution such as an execution refractive index of the optical waveguide (calculated from the width of the core pattern). An optical circuit to be manufactured by a glass film forming method by a flame deposition method, the optical circuit being manufactured by a step of forming a lower cladding film, a step of forming a core film, and a step of forming a core pattern by photolithography, in which refractive index distribution of the lower cladding in a wafer plane, refractive index distribution of the core film, a film thickness, and in-plane distribution of an effective refractive index of an optical waveguide calculated from a width of the core pattern are fed forward to manufacturing of an upper cladding, so that there is an effect of reducing distribution (bias) of characteristics in the wafer plane of a silica-based planar lightwave circuit.

### Example 3

The effective refractive index may be adjusted by providing in-plane distribution to the refractive index of the upper cladding so that the circuit characteristics in the wafer plane maintain desired values. As described above, it is possible to control the in-plane distribution of the in-plane upper cladding at the time of upper cladding deposition. Thus, the refractive index of the upper cladding may be controlled in order to obtain desired optical circuit characteristics.

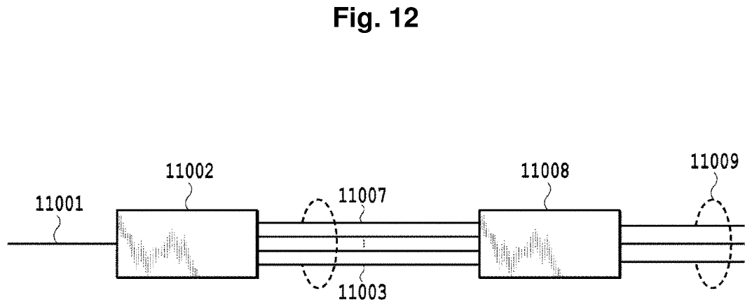

FIG. 12 is a view according to the present example. FIG. 12 is an arrayed waveguide grating and includes an input waveguide 11001, an input slab waveguide 11002, arrayed waveguides 11003 to 11007, an output slab waveguide 11008, and an output waveguide 11009. FIG. 12 illustrates an example in which the number of arrayed waveguides 11003 to 11007 is 5, but the number of arrayed waveguides is not limited to 5. In the arrayed waveguide grating of FIG. 12, the arrayed waveguides 11003 to 11007 are all formed to have the same length. In other words, the path length difference is zero (the path length difference is defined as a length on the layout, and the optical path length difference is defined as an optical length). With reference to the graph of FIG. 8(b), deposition is performed while adjusting the refractive index of the upper cladding so that the effective refractive index of the arrayed waveguide 11003 becomes low and the effective refractive index of the arrayed waveguide 11007 becomes high. As a result, the optical path length difference between the arrayed waveguides increases as the array number increases, and it is possible to achieve a wavelength demultiplexing function which is a desired function of the arrayed waveguide grating.

### Another Example 1

As a method using a secondary measurement value, a method (referred to as selective exposure) described in detail below will be described. Here, an example of a silica-based planar lightwave circuit will be described.

In the first embodiment described above, an example has been described in which the measurement data processing unit predicts the optical characteristics from the measurement data of the control values of the manufacturing apparatus, and the control data processing unit generates the measurement values of the control data for controlling the manufacturing apparatus in the next and subsequent steps. However, as described below, it is also possible to separately acquire characteristic data of the wafer using the measurement apparatus for the wafer in process during each manufacturing step and perform correction using the manufacturing apparatus and method for performing correction.

Here, a method for manufacturing a silica-based planar lightwave circuit will be described with reference to a manufacturing step of an optical waveguide device illustrated in FIG. 1, but it is obvious that an optical waveguide including a cladding and a core as described later can be applied to other materials, for example, a semiconductor such as InP and a ferroelectric waveguide such as LiNbO₃.

A silica-based planar lightwave circuit is mechanically and chemically stable and is applied to a functional device such as a wavelength filter and an optical switch by an interferometer, and typical interference devices include an arrayed waveguide grating. The center wavelength of the arrayed waveguide grating is expressed as:

Math. 9

λ₀=n_{eff}dL/m Formula (6).

The manufacturing stability depends on the effective refractive index n_{eff}. By the way, in the FHD method to be used in the film formation of the core 13 in step 2 in FIG. 1, the source gas hydrolyzed by the burner is sprayed onto the wafer installed on the rotating turntable to burn soot of the glass. In this event, the film thickness and the refractive index fluctuate in a wafer plane due to various causes such as an environmental temperature, fluctuation of rotation speed of the turntable and discretization and fluctuation of an orbit of the burner. Thus, the effective refractive index neff also fluctuates in the wafer plane. The effective refractive index n_{eff} felt by the light wave guiding the optical waveguide depends on the refractive indexes of the bulk of the core 13, the lower cladding 12, and the upper cladding 19, and the dimensional shape of the processed core pattern 18, but most of the light energy is confined inside the core pattern 18, so that the refractive index and the size of the processed core pattern 18 greatly affect.

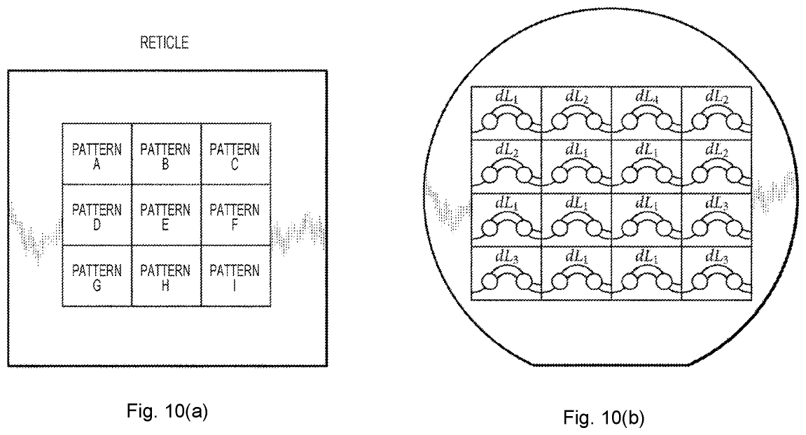

In the present embodiment, a method will be described in which the film thickness and the distribution of the refractive index of the wafer in the plane after the film formation of the core 13 are measured using a measurement apparatus, measurement data is acquired, and the distribution is corrected in the photolithography step in step 4. In general, an optical waveguide device to be manufactured on a wafer is manufactured by disposing a plurality of chips Shot 1 to 16 on the wafer. The core 13 has distribution in the refractive index and the film thickness in the wafer plane, and thus, each chip has optical characteristics reflecting the distribution. Thus, in the present embodiment, as illustrated in FIG. 10(a), patterns A to I of the optical circuit that compensates for the distribution of the refractive index and the film thickness are exposed for each position to correct the distribution of the optical characteristics. Note that the correction can also be performed separately using a manufacturing apparatus that performs correction.

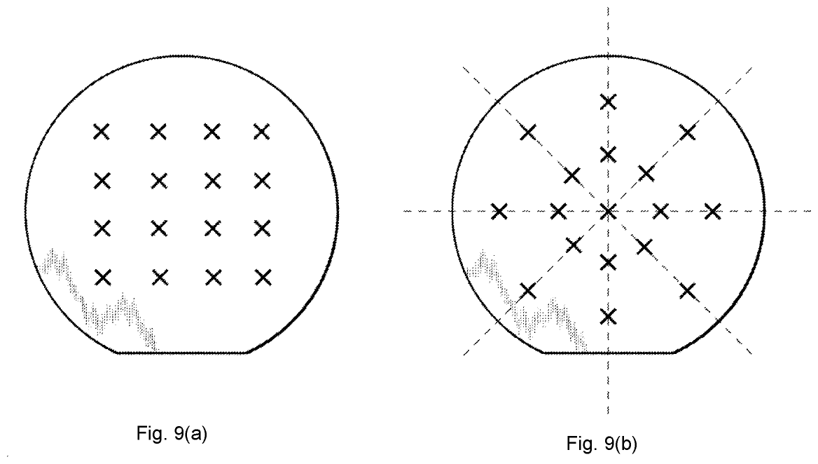

First, after the film formation of a core in step 2, the film thickness and refractive index distribution of the core film are measured by a method such as ellipsometry. In the measurement, as illustrated in FIGS. 9(a) and 9(b), grid-like points in the wafer or points placed on polar coordinates (r, θ) are selected as representative points. Subsequently, approximate formulas n(x, y) and t(x, y) of the film thickness and the refractive index are generated by the following formula with reference to the representative points obtained by measuring the refractive index and the film thickness of the core 13.

Math. 10

n(x,y)=Σₖ₌₀^{K}^{ₓ}aₖx^{k}+Σₖ₌₀^{K}^{_{y}}bₖy^{k},t(x,y)=Σₖ₌₀^{K}^{ₓ}cₖx^{k}+Σₖ₌₀^{K}^{_{y}}dₖy^{k} Formula (8)

Here, aₖ, bₖ, cₖ, and dₖ are coefficients and are obtained using a least squares method, or the like. In correcting the optical characteristics for each chip, n(x, y) and t(x, y) at each arrangement place are calculated using the above approximate formula. For example, in a case where an arrayed waveguide grating is assumed as an optical circuit type to be manufactured, n(xₚ, yₚ), t(xₚ, yₚ) in an arrayed waveguide portion (xₚ, yₚ) which is an interferometer portion is obtained.

Three effective refractive index correction methods will be described below.

In the first distribution correction method, patterns having different optical path length differences of the arrayed waveguides are arranged. The effective refractive index of the optical waveguide greatly depends on the refractive index of the core pattern 18 as described above, and thus, the refractive index of the bulk of the core may be mainly considered in the first order approximation. Thus, the effective refractive index n_{eff}(xₚ, yₚ) at the arrayed waveguide position (xₚ, yₚ) of the effective refractive index is expressed as a function of n(x, y), t(x, y), wₙₒᵣₘ:

Math. 11

n_{eff}(xₚ, yₚ)=f(n(xₚ, yₚ), t(xₚ, yₚ), wₙₒᵣₘ) Formula (9)
by setting the nominal value of the finished width of the core pattern 18 as wₙₒᵣₘ. A function

Math. 12

f( [symbol] )
is a function expressed by a Marquarry method, an imaginary axis propagation method, an equivalent refractive index method, or the like. Assuming that a target range of the center wavelength of the arrayed waveguide grating is set as λₙₒᵣₘ±δλ with respect to n_{eff}(xₚ, yₚ) obtained by the above formula, if the arrayed waveguide pattern has the optical path length difference dL between the arrays satisfying:

Math. 13

dL=m(λₙₒᵣₘ±δλ)/n_{eff}(xₚ, yₚ) Formula (10),
an arrayed waveguide grating having a desired center wavelength can be obtained. Thus, as illustrated in FIG. 10(b), a plurality of reticles having circuit patterns (for example, dL₁, dL₂, dL₃, dL₄, and the like) of the arrayed waveguide gratings having different optical path length differences dL of the arrayed waveguides are prepared, and a pattern corresponding to the (xₚ, yₚ) is selected and exposed in step 4, so that desired target characteristics of the center wavelength of the arrayed waveguide grating can be obtained. In other words, it is only necessary to select from a plurality of prepared patterns, the arrayed waveguide grating pattern having the optical path length difference dL of the arrayed waveguide satisfying:

$$\begin{matrix}Math . 14 & \\ \frac{m ( {λ}_{norm} - δλ )}{{n}_{eff} ( {x}_{p} , {y}_{p} )} \leq dL \leq \frac{m ( {λ}_{norm} + δλ )}{{n}_{eff} ( {x}_{p} , {y}_{p} )} & Formula ( 11 )\end{matrix}$$

and perform exposure. In the present example, the arrayed waveguide grating pattern is selected, and exposure is performed.

By the way, as the plurality of circuit patterns to be prepared, it is preferable to overlap ranges of the optical path length differences dL of the arrayed waveguides to some extent in consideration of the influence of manufacturing fluctuation in a subsequent step. For example, in a case where dλ is a positive value, and a target center wavelength is expressed as follows:

Math. 15

λ₀−dλ≤λ₀≤λ₀+dλ Formula (12),
an optical path length difference dL₀ of the arrayed waveguide when a core film with ideal (nominal value) effective refractive index

$$\begin{matrix}Math . 16 & \\ {n}_{eff}^{norm} & \end{matrix}$$

$$is obtained , is set at$$

$$\begin{matrix}Math . 17 & \\ {dL}_{0} = \frac{m {λ}_{0}}{{n}_{eff}^{norm}} , & Formula ( 13 )\end{matrix}$$

$$assuming that σ > 0 ,$$

$$\begin{matrix}Math . 18 & \\ {dL}_{- 1} = \frac{m ( {λ}_{0} - d λ + σ )}{{n}_{eff}^{norm}} & Formula ( 14 )\end{matrix}$$

$$\begin{matrix}Math . 19 & \\ {dL}_{1} = \frac{m ( {λ}_{0} + d λ - σ )}{{n}_{eff}^{norm}} & Formula ( 15 )\end{matrix}$$

$$\begin{matrix}Math . 20 & \\ {dL}_{- 2} = \frac{m ( {λ}_{0} + 2 d λ - 2 σ )}{{n}_{eff}^{norm}} & Formula ( 16 )\end{matrix}$$

$$\begin{matrix}Math . 21 & \\ {dL}_{2} = \frac{m ( {λ}_{0} + 2 d λ - 2 σ )}{{n}_{eff}^{norm}} & Formula ( 17 )\end{matrix}$$

it is preferable to dispose on the reticle, a pattern of an arrayed waveguide grating having an optical path length difference satisfying Formula (14) to Formula (17).

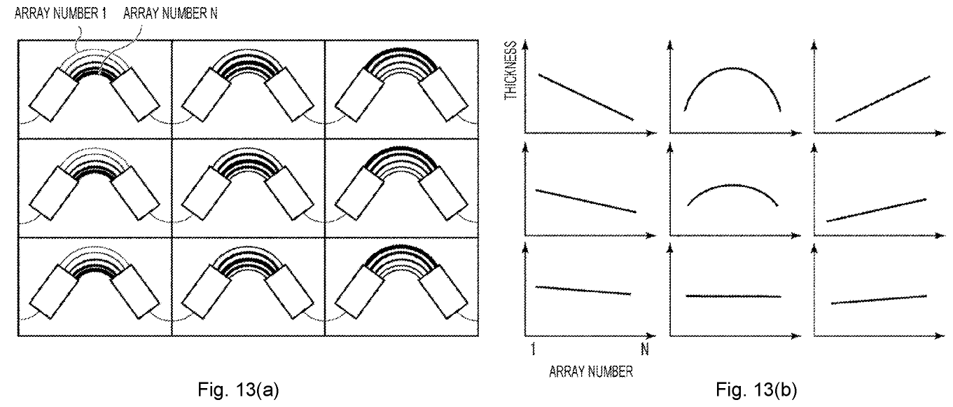

In the second correction method, circuit patterns having different waveguide widths are arranged. As described above, the effective refractive index n_{eff}(xₚ, yₚ) is a function of n(xₚ, yₚ), t(xₚ, yₚ) in (xₚ, yₚ) and the width W. Thus, as illustrated in FIG. 13, a circuit pattern having an arrayed waveguide width of the width W such that the effective refractive index has a desired value (constant value) may be exposed. Also in this case, a plurality of circuit patterns having a plurality of arrayed waveguide widths may be prepared and selected.

In the second correction method, optical characteristics other than the center wavelength described above can be corrected. In general, in a multiple beam interferometer such as an arrayed waveguide grating, a phase error between beam fluxes limits its definition. In other words, the phase error determines crosstalk performance of different wavelengths in optical communication. Thus, in a case where there is distribution of the effective refractive index inside a region where the arrayed waveguide exists, an arrayed waveguide grating having a width for correcting the deviation of the effective refractive index from the desired value may be prepared for each point (xₚᵢ, yₚᵢ) inside the region.

FIG. 13 is a pattern of a photomask in which arrayed waveguide gratings for compensating for crosstalk performance are arranged. FIG. 13(a) is a view illustrating arrangement of the reticles. FIG. 13(b) is a view illustrating a thickness of the arrayed waveguide of each reticle pattern.

A plurality of circuits having different arrayed waveguide distribution is arranged in the photomask. In the figure, as illustrated on the right side, arrayed waveguide gratings having different waveguide width distribution are arranged in a matrix of 3×3 for the arrayed waveguide numbers. The matrix is laid out such that, in the arrayed waveguide gratings in the left column, widths of arrayed waveguides having younger numbers are wider, in the arrayed waveguide gratings in the right column, widths of arrayed waveguides of older numbers are wider, and in the arrayed waveguide gratings in the middle column, a waveguide at the center of the arrayed waveguide is wide and has second-order distribution. Furthermore, in the upper row, an absolute value of the gradient of the distribution is large, in the middle row, the absolute value is moderate, and in the lower row, the absolute value is small. Here, a combination of 3×3 has been described, and a combination in which the gradient of the thickness of the arrayed waveguide is first order or second order has been described. However, a combination having thickness distribution expressed by a general polynomial may be arranged in the photomask.

In the third distribution correction method, the distribution is corrected by adjusting an exposure period. Generally, the width of the waveguide can be changed by changing the exposure period, a development period, and concentration of a developer. Thus, the exposure period may be changed for each arrayed waveguide grating circuit present at each point (xₚ, yₚ). In addition, in a case where it is desired to change the width of the waveguide over the entire wafer, for example, in a case where the core film is formed to have a large or small refractive index over the entire wafer, it is also possible to adjust the width of the waveguide over the entire wafer by changing the concentration of the developer or the development period.

Although the arrayed waveguide grating has been described above as an example, the present invention is also applicable to an interferometer typified by a matrix switch using two-beam interference such as a Mach-Zehnder interferometer or a filter such as a Bragg diffraction grating. In addition, in a spot size converter, or the like, to be used to reduce a connection loss between an optical waveguide and an optical fiber, a field system of an optical wave affects characteristics thereof. The effective refractive index of the field system is one of the parameters, and thus, it is clear that the above method can be applied.

The refractive index distribution of the upper cladding 11 in step 8 of deposition of the upper cladding 19 which is the subsequent step can be adjusted using the measurement data of the refractive index distribution in the wafer plane of the lower cladding 19, the refractive index distribution of the core film, and/or the film thickness of the core film, and the in-plane distribution of the effective refractive index of the optical waveguide calculated from the width of the core pattern 18.

1. An apparatus for manufacturing an optical circuit including a glass film, the apparatus comprising:
a step of forming a lower cladding film and an apparatus configured to form a core film;
an apparatus configured to form a core pattern by photolithography; and
an apparatus configured to form an upper cladding film on the core pattern,
wherein in the step of forming the upper cladding film, refractive index distribution of the upper cladding is adjusted on a basis of measurement data of refractive index distribution in a layer of the optical circuit before the step of forming the upper cladding film.

2. The apparatus for manufacturing the optical circuit according to claim 1, wherein the measurement data is refractive index distribution of the lower cladding in a wafer plane, refractive index distribution and/or a film thickness of the core film, and in-plane distribution of an effective refractive index of an optical waveguide calculated from a width of the core pattern.

3. The apparatus for manufacturing the optical circuit according to claim 1, wherein the refractive index distribution of the upper cladding is adjusted such that the optical circuit to be formed by a silica-based planar lightwave satisfies desired circuit characteristics.

4. The apparatus for manufacturing the optical circuit according to claim 2, wherein the refractive index distribution of the upper cladding is adjusted such that an effective refractive index of the optical waveguide becomes constant in a plane.

5. The apparatus for manufacturing the optical circuit according to claim 1, wherein a refractive index of the upper cladding is adjusted by one or both of P₂O₅ and B₂O₃.

6. The apparatus for manufacturing the optical circuit according to claim 1, wherein the refractive index of the upper cladding is adjusted by adding GeO₂, TiO₂, Ta₂O₅, HfO₂, or ZrO₂.

7. A method for manufacturing an optical circuit including a glass film, the method comprising:
a step of forming a lower cladding film and a step of forming a core film;
a step of forming a core pattern by photolithography; and
a step of forming an upper cladding film on the core pattern,
wherein in the step of forming the upper cladding film, refractive index distribution of the upper cladding is adjusted on a basis of measurement data of refractive index distribution in a layer of the optical circuit before the step of forming the upper cladding film.

8. The method for manufacturing the optical circuit according to claim 7,
wherein the measurement data is refractive index distribution of the lower cladding in a wafer plane, refractive index distribution and/or a film thickness of the core film, and in-plane distribution of an effective refractive index of an optical waveguide calculated from a width of the core pattern.

9. The method for manufacturing the optical circuit according to claim 7, wherein the refractive index distribution of the upper cladding is adjusted such that the optical circuit to be formed by a silica-based planar lightwave satisfies desired circuit characteristics.

10. The method for manufacturing the optical circuit according to claim 8,
wherein the refractive index distribution of the upper cladding is adjusted such that an effective refractive index of the optical waveguide becomes constant in a plane.

11. The method for manufacturing the optical circuit according to claim 7,
wherein a refractive index of the upper cladding is adjusted by one or both of P₂O₅ and B₂O₃.

12. The method for manufacturing the optical circuit according to claim 7,
wherein the refractive index of the upper cladding is adjusted by adding GeO₂, TiO₂, Ta₂O₅, HfO₂, or ZrO₂.
